(19) United States
(12) Patent Application Publication
(10) Pub. No.: US 2009/0139086 A1
(43) Pub. Date: Jun. 4, 2009

(54) METHOD FOR MANUFACTURING PRINTED CIRCUIT BOARD

(75) Inventors: TSO-HUNG YEH, Tayuan (TW); HUNG-YI CHANG, Tayuan (TW); CHIA-CHENG CHEN, Tayuan (TW)

Correspondence Address: PCE INDUSTRY, INC.;ATT. Steven Reiss, 458 E. LAMBERT ROAD, FULLERTON, CA, 92835, US

(73) Assignee: FOXCONN ADVANCED TECHNOLOGY INC., Tayuan (TW)

(21) Appl. No.: 12/207,333

(22) Filed: Sep. 9, 2008

(30) Foreign Application Priority Data
Nov. 29, 2007 (CN) 200710202764.9

(51) Int. Cl. H05K 3/10; H05K 3/36

(52) U.S. Cl. 29/852; 29/830; 29/846

(57) ABSTRACT

The present invention relates to a method for manufacturing printed circuit boards. A substrate including a base and two conductive layers on two opposite surfaces of the base is provided. A through-hole passing through the base and the conductive layers is defined in the substrate. A metal layer is formed on the substrate. The metal layer has a first portion on an outer surface of the substrate and a second portion on an inner surface in the through-hole thereof. A protecting material is applied onto the metal layer in the through-hole, an unwanted section of the first portion of the metal layer is removed. Electrical traces in each of the conductive layers are formed.

### BACKGROUND

1. Technical Field

The present invention generally relates to printed circuit boards, and particularly relates to a method for manufacturing a printed circuit board.

2. Discussion of Related Art

With the development of science and technology, microphones, portable computers and other electronic products have achieved ever greater levels of miniaturization, thereby leading to the development of double-sided printed circuit board and multilayer printed circuit board technology using via-holes.

A typical method for manufacturing the double-sided printed circuit board with through-holes includes the following steps. Firstly, a substrate including a base and two conductive layers disposed on two opposite surfaces of the base is provided. Secondly, a photoresist layer is attached onto each of the two conductive layers, and the photoresist layer is exposed with a plastic photomask having a predetermined pattern. Thirdly, after exposure, a portion of the photoresist layer is dissolved with a developing agent, while the residual insoluble photoresist layer forms a desired pattern. As a result, the residual portion of the photoresist layer covering the conductive layers protects the conductive layers from corrosion. Fourthly, the uncovered portion of the conductive layers is etched and removed from the resin layer using an etchant. Fifthly, the photoresist layers covering the conductive layers are removed to obtain the desired electrical traces. Sixthly, a number of through-holes are formed in a predetermined region of the electrical traces using a laser ablating method or a mechanical drilling process. Lastly, a metal layer is plated on an inner surface of each of the through-holes using a plating method to obtain a printed circuit board having through-holes.

However, during the plating process, the metal such as copper is inevitably deposited on the electrical traces simultaneously with being deposited on the inner surface of each of the through-holes. Therefore, a thickness of each of the electrical traces is increased, thus a size of the electrical trace will be larger than that of predetermined.

What is needed, therefore, is a method for manufacturing a printed circuit board to overcome the above-described problems.

### SUMMARY

One embodiment provides a method for manufacturing a printed circuit board having a through-hole. A substrate including a base and two conductive layers on two opposite surfaces of the base is provided. A through-hole passing through the base and the conductive layers is defined in the substrate. A metal layer is formed on the substrate. The metal layer has a first portion on an outer surface of the substrate and a second portion on an inner surface in the through-hole thereof. A protecting material is applied onto the metal layer in the through-hole, an unwanted section of the first portion of the metal layer is removed. Electrical traces in each of the conductive layers are formed.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of embodiments. Moreover, in the drawings, like reference numerals designate corresponding parts throughout the different views.

FIG. 1 is a flow chart showing a process of manufacturing a printed circuit board according to an exemplary embodiment;

FIG. 2 is a cross-sectional view of a substrate;

FIG. 3 is similar to FIG. 2, but showing a through-hole defined in the substrate;

FIGS. 4˜5 are similar to FIG. 3, but showing a metal layer formed on the substrate;

FIG. 6 is similar to FIG. 5, but showing a photoresist film formed on the substrate;

FIG. 7 is similar to FIG. 6, but showing an exposing step of the photoresist film;

FIG. 8 is similar to FIG. 7, but showing a developing step of the photoresist film;

FIG. 9 is similar to FIG. 7, but showing unwanted portions of the metal layer is removed; and

FIG. 10 is similar to FIG. 7, but showing a step of forming electrical traces.

### DETAILED DESCRIPTION OF EMBODIMENT

An embodiment will be described in detail below and with reference to the drawings.

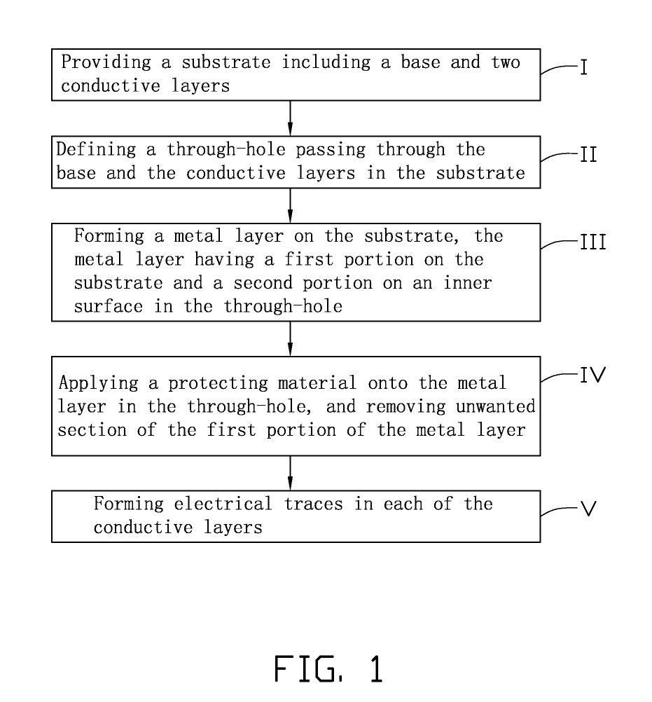

Referring to FIGS. 1˜10, a method for manufacturing a printed circuit board having at least one through-hole includes the following steps. Firstly, a substrate including a base and two conductive layers on two opposite surfaces of the base is provided. Secondly, a through-hole passing through the base and the conductive layers is defined in the substrate. Thirdly, a metal layer is formed on the substrate. The metal layer has a first portion on an outer surface of the substrate and a second portion on an inner surface in the through-hole thereof. Fourthly, a protecting material is applied onto the metal layer in the through-hole, an unwanted section of the first portion of the metal layer is removed. Lastly, Electrical traces in each of the conductive layers are formed, thus obtaining a printed circuit board having at least one through-hole.

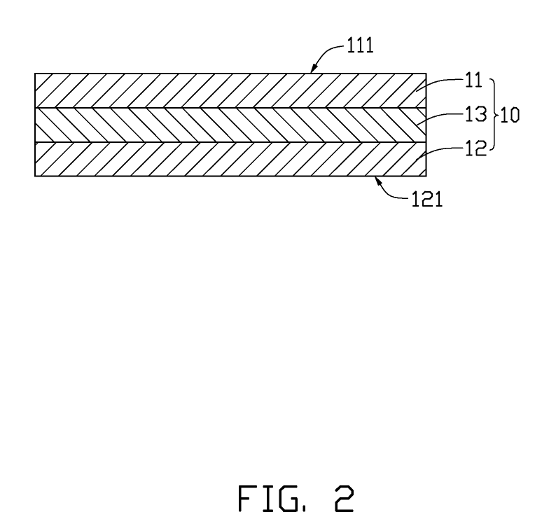

In step I, as shown in FIG. 2, a substrate 10 is provided. The substrate 10 is a double-sided structure including a base 13, a first conductive layer 11 and a second conductive layer 12. The first conductive layer 11 and the second conductive layer 12 are formed on two opposite surfaces of the base 13. The base 13 can be a insulating resin layer or an overlap structure of a unit including a insulating resin layer and two conductive layers deposed on two opposite surfaces of the resin layer. In the present embodiment, the base 13 is a insulating resin layer. The first conductive layer 11 defines a first outer surface 111, the second conductive layer 12 defines a second outer surface 121. The first conductive layer 11 and the second conductive layer 12 are made of copper. Preferably, a thickness of each of the first conductive layer 11 and the second conductive layer 12 is less than 12 micrometers.

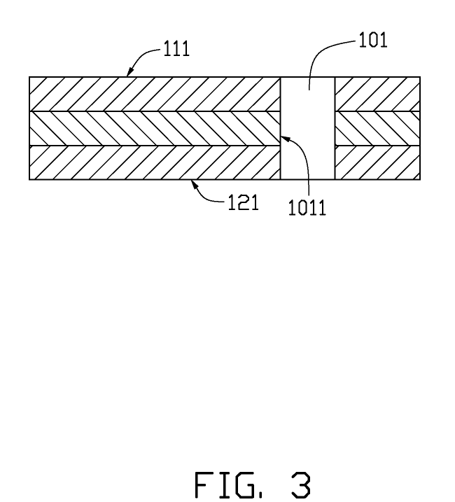

In step II, as shown in FIG. 3, a through-hole 101 passing through the first outer surface 111 and the second outer surface 121 is formed in the substrate 10, thus defining an inner surface 1011 of the substrate 100 therein. The through-hole 101 can be formed in the substrate 10 using mechanical drilling method or laser ablating process. In the present embodiment, the through-hole 101 is formed using a laser ablating process.

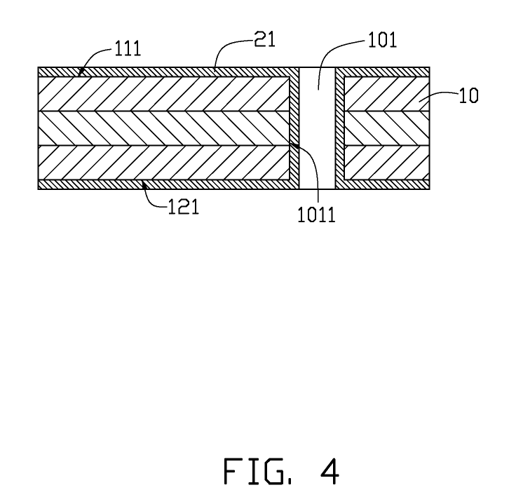

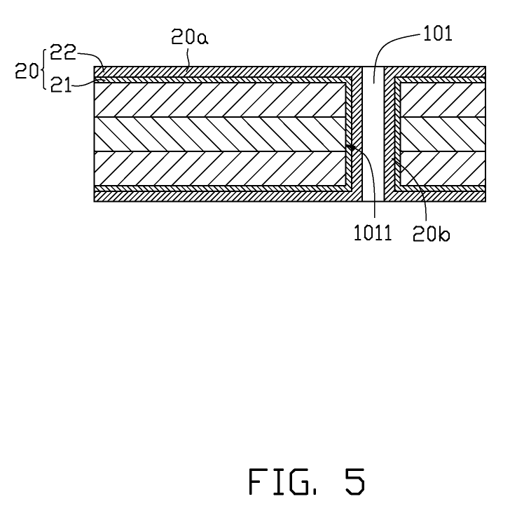

In step III, as shown in FIG. 4 and FIG. 5, the substrate 10 is plated with metal, thus a metal layer 20 is deposited on the inner surface 1011, the first outer surface 111 and the second outer surface 121 simultaneously. The metal layer 20 can be formed using electro-less plating process, electro-plating process or a combination of an electro-less plating and an electro-plating process. In the present embodiment, the metal layer 20 is formed using the combination of the electro-less plating and an electro-plating process. In detail, firstly, a first copper layer 21 is electro-less plated on the inner surface 1011, simultaneously, formed on the first outer surface 111 and the second outer surface 112. Secondly, a second copper layer 22 is electro-plated on the first copper layer 21. Therefore, the metal layer 20 is composed of the first copper layer 21 and the second copper layer 22, and a first portion 20a of the metal layer 20 is on the first outer surface 111 and the second outer surface 121 and a second portion 20b of the metal layer 20 is on the inner surface 1011.

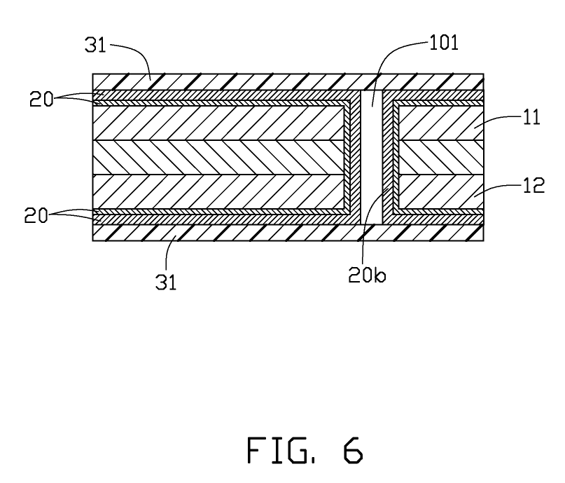

In step IV, as shown in FIG. 6˜9, the second portion 20b of the metal layer 20 is protected, and an unwanted portion 20c of the first portion 20a is removed.

Firstly, referring to FIG. 6, two photoresist films 31 are attached onto the metal layer 20. The two photoresist films 31 are configured for protecting the second portion 20b from being etched by etchant when electrical traces are formed using chemical etching method in the first conductive layer 11 and the second conductive layer 12. The two photoresist films 31 are attached on the first outer surface 111 and the second outer surface 112 respectively and cover the through-hole 101.

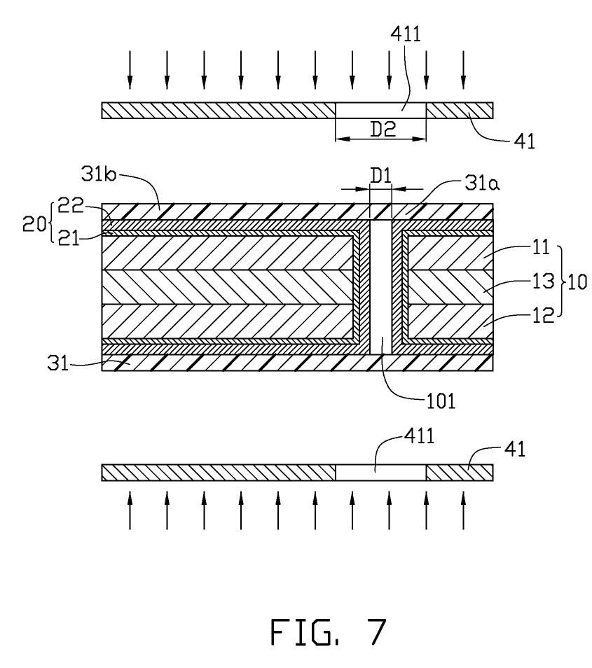

Secondly, referring to FIG. 7, two photo-masks 41 are provided. Each of the photo-masks 41 defines a through-hole 411 therein. A diameter of the through-hole 411 (denoted by D₂) is more than a diameter of the through-hole 101 (denoted by D₁). Each of the photoresist films 31 is exposed to the corresponding through-hole 411 of the photo-mask 41. As a result, a portion of each of the two photoresist film 31 corresponding to the through-hole 411 is insoluble, and the residual portion of the photoresist film 31 is soluble. Therefore, each of the two photoresist films 31 includes an insoluble portion 31a and a soluble portion 31b.

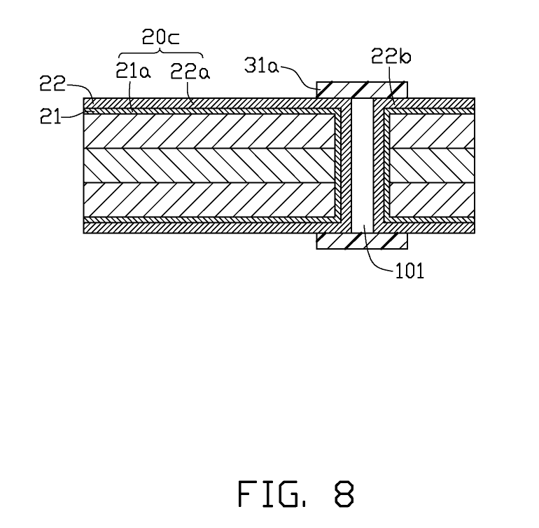

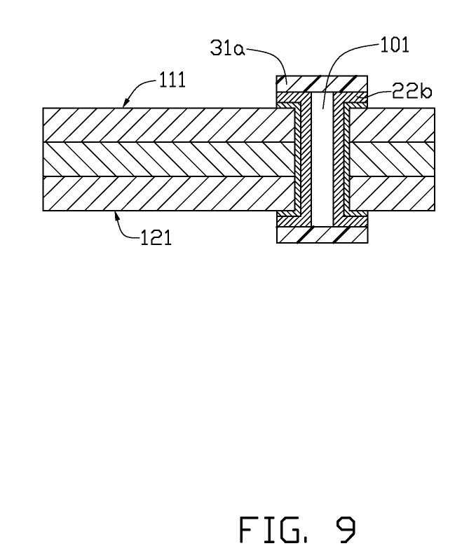

Thirdly, the soluble portion 31b is removed using a developing process, referring to FIG. 8, thus the through-hole 101 is covered by the insoluble portion 31a. Simultaneously, a first portion 22a of the second copper layer 22 corresponding to the soluble portion 31b is uncovered, and a second portion 22b of the second copper layer 22 is covered by the insoluble portion 31a.

Fourthly, referring to FIGS. 8˜9, an unwanted portion 20c of the first portion 20a is removed. In the present embodiment, the unwanted portion 20c is composed of the first portion 22a and a third portion 21a of the first copper layer 21 corresponding to the first portion 22a. In detail, the first portion 22a is etched and removed using an etchant, and then the third portion 21a is etched. Thus, the first outer surface 111 and the second outer surface 121 are exposed.

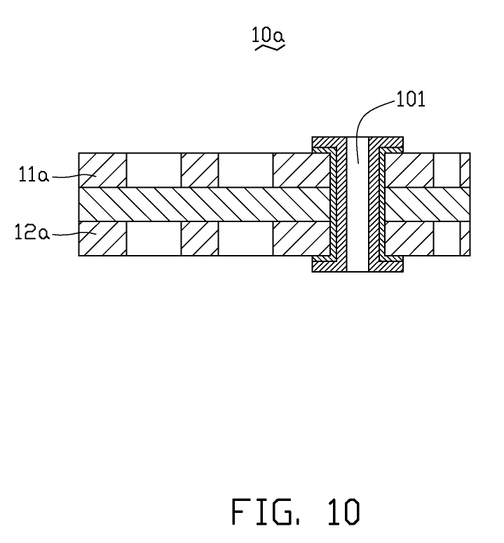

In step V, as shown in FIG. 10, a first electrical trace 11a is formed in the first conductive layer 11, and a second electrical traces 12a is formed in the second conductive layer 12. Thus, a printed circuit board 110a having a through hole 101 is obtained.

The first electrical trace 11a and the second electrical trace 12a are formed using a chemical etching method.

In another embodiment, a liquid photoresist fills into the through-hole 101 to protect the metal on the inner surface 1011 from etching in the process of forming electrical traces in the first conductive 11 and the second conductive 12. The thickness of each of the first conductive layer 11 and the second conductive layer 12 is more than 12 micrometers. In order to obtain 12 micrometers thick electrical traces, after etching the third portion 21a, a portion of the first conductive layer 11 and a portion of the second conductive layer 12 corresponding to the third portion 21a should be etched and removed simultaneously, until the thickness of each of the first conductive layer 11 and the second conductive layer 12 is less than 12 micrometers.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A method for manufacturing a printed circuit board, the method comprising:
providing a substrate including a base and two conductive layers on two opposite surfaces of the base;
defining a through-hole in the substrate, the through hole passing through the base and the conductive layers;
forming a metal layer on the substrate, the metal layer having a first portion on an outer surface of the substrate and a second portion on an inner surface in the through-hole thereof;
applying a protecting material onto the metal layer in the through-hole, and removing unwanted section of the first portion of the metal layer; and
forming electrical traces in each of the conductive layers.

2. The method as claimed in claim 1, wherein the protecting material includes a liquid photoresist filled into the through-hole.

3. The method as claimed in claim 1, wherein the protecting material includes a photoresist film formed onto the two conductive layers.

4. The method as claimed in claim 1, wherein the unwanted sections of the first portion of the metal layer is removed using a chemical etching method.

5. The method as claimed in claim 1, wherein the unwanted sections of the first portion of the metal layer is removed using an etching process such that a combined thickness thereof the first portion of the metal layer and the respective conductive layer is less than 12 micrometers.

6. The method as claimed in claim 1, wherein the through-hole is formed using a mechanism drilling process or a laser ablating process.

7. The method as claimed in claim 1, wherein the substrate is plated using an electro-less plating process, an electro-plating process or a combination thereof.

8. The method as claimed in claim 1, wherein the electrical traces are formed using a chemical etching method.

9. A method for manufacturing a printed circuit board, the method comprising:
providing a substrate including an insulating base and electrically conductive layers respectively formed on opposite surfaces of the base;
defining a through-hole in the substrate, the through hole passing through the base and the conductive layers;
forming a metal layer on the substrate, the metal layer having a first portion on an outer surface of electrically conductive layers of the substrate and a second portion on an inner surface in the through-hole thereof;
applying a photoresist material on the second portion of the metal layer and removing unwanted section of the first portion of the metal layer by etching, wherein the second portion of the metal layer is protected by the photoresist material from being etched and is left intact; and
forming electrical traces in each of the conductive layers.
